(19) United States
(12) Patent Application Publication
(10) Pub. No.: US 2026/0319535 A1
(43) Pub. Date: Oct. 15, 2026

(54) METHODS AND APPARATUSES FOR MANAGING INPUT/OUTPUT INTERFACES

(71) Applicant: Yangtze Memory Technologies Co., Ltd., Wuhan (CN)

(72) Inventor: Weifeng GONG, Wuhan (CN)

(21) Appl. No.: 19/226,437

(22) Filed: Jun. 3, 2025

(30) Foreign Application Priority Data
Apr. 14, 2025 (CN) 202510460195.6

(51) Int. Cl. G05F 1/565; G05F 1/46; G05F 1/62

(52) U.S. Cl. CPC G05F 1/565; G05F 1/468; G05F 1/62

(57) ABSTRACT

Methods, devices, apparatuses, and systems for managing input/output interfaces are provided. In one aspect, a method includes obtaining a voltage level of an input signal received from a host device, configuring, based on the voltage level of the input signal, a power domain of an interface of a slave device coupled to the host device, and sending an output signal to the host device, where a voltage level of the output signal is set based on the power domain.

### CROSS-REFERENCE TO RELATED APPLICATIONS

This application claims priority to Chinese Patent Application No. 202510460195.6, filed on Apr. 14, 2025, which is hereby incorporated by reference in its entirety.

### TECHNICAL FIELD

The present disclosure generally relates to electronic devices, and in particular, to managing input/output (IO) interfaces of electronic devices.

### BACKGROUND

A slave device, such as a removable storage medium including an SD card or a flash memory, can be connected to a host device such as a personal computer. The slave device can access and store data while receiving a power supply from the host device.

### SUMMARY

The present disclosure involves methods, apparatuses, and systems for managing input/output (IO) interfaces of slave devices.

One aspect of the present disclosure provides a method. The method includes obtaining a voltage level of an input signal received from a host, configuring, based on the voltage level of the input signal, a power domain of an interface of a slave device coupled to the host, and sending an output signal to the host, where a voltage level of the output signal is set based on the power domain.

In some implementations, the voltage level of the output signal is the same as the voltage level of the input signal.

In some implementations, the input signal and the output signal are transmitted through one or more pins of the interface. The one or more pins belong to a power domain group and are configured to have the same voltage when voltage levels of the one or more pins are set high.

In some implementations, the method includes obtaining a voltage level at a first pin of one or more pins of the interface that belong to a power domain group, where the voltage level of the first pin is set high.

In some implementations, configuring the power domain includes latching, to a latch, a first indicator indicating the voltage level of the input signal, sending a second indicator from the latch to a voltage regulator, where the second indicator is determined based on the first indicator and indicates the power domain, and configuring the power domain according to the second indicator by configuring an output of the voltage regulator.

In some implementations, the voltage regulator is a low drop-out (LDO) regulator or a buck regulator.

In some implementations, the method further includes releasing a reset signal after the power domain is configured to match the voltage level of the input signal.

In some implementations, the input signal and the output signal are sideband input/output signals or system management bus (SMBUS) signals.

In some implementations, the voltage level of the input signal is obtained during a reset period, and the output signal to the host device is sent during a communication period that follows the reset period.

In some implementations, the slave device is a memory system.

Another aspect of the present disclosure features a slave device having an interface. The interface includes a first circuit configured to obtain a voltage level of an input signal received from a host device, a second circuit configured to determine, based on the voltage level of the input signal, a power domain of the interface, and a third circuit configured to send an output signal to the host device, where a voltage level of the output signal is set based on the power domain.

In some implementations, the first circuit includes a first comparator configured to receive the input signal and a first reference signal, and output a first bit indicating whether the voltage level of the input signal is set high. The first circuit further includes a second comparator configured to receive the input signal and a second reference signal, and output a second bit indicating whether the voltage level of the input signal corresponds to a first power domain or a second power domain.

In some implementations, the second circuit includes a latch configured to receive and store the second bit, and a voltage regulator configured to output, based on the second bit, a voltage corresponding to one of the first power domain or the second power domain.

In some implementations, an output of the second circuit is coupled to the third circuit and provides power for the third circuit.

In some implementations, the first circuit and the second circuit are configured to receive a supply voltage.

In some implementations, the voltage level of the output signal is the same as the voltage level of the input signal.

In some implementations, the interface comprises one or more pins that belong to a power domain group, wherein the one or more pins are configured to transmit the input signal and the output signal. The one or more pins are configured to have the same voltage when voltage levels of the one or more pins are set high.

A further aspect of the present disclosure features a memory system including a memory device, a control circuit, and an interface. The interface is configured to obtain a voltage level of an input signal received from a host device, determine, based on the voltage level of the input signal, a power domain of the interface, and send an output signal to the host device, wherein a voltage level of the output signal is set based on the power domain.

In some implementations, the interface includes a first circuit configured to obtain the voltage level of the input signal, a second circuit configured to determine, based on the voltage level of the input signal, the power domain of the interface, and a third circuit configured to send the output signal to the host device.

In some implementations, the first circuit includes a first comparator configured to receive the input signal and a first reference signal, and output a first bit indicating whether the voltage level of the input signal is set high, and a second comparator configured to receive the input signal and a second reference signal, and output a second bit indicating whether the voltage level of the input signal corresponds to a first power domain or a second power domain.

An additional aspect of the present disclosure features system including a host device and a slave device coupled to the host device through an interface of the slave device. The interface is configured to obtain a voltage level of an input signal received from the host device, determine, based on the voltage level of the input signal, a power domain of the interface, and send an output signal to the host device, wherein a voltage level of the output signal is set based on the power domain.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example input/output (IO) interface of a host device and an example input/output interface of a slave device in a host-slave system.

FIG. 2 illustrates a block diagram of example circuits of an IO interface of a slave device.

FIG. 3 illustrates a schematic timing diagram of an example signal transmission process.

FIG. 4 illustrates a schematic diagram of an example IO voltage detection circuit.

FIG. 5 illustrates a block diagram of an example IO power configuration circuit.

FIG. 6 illustrates an example process of managing an IO interface of a slave device.

FIG. 7 illustrates a block diagram of an example system having an example memory system.

FIGS. 8A-8B illustrate example storage products.

FIG. 9 illustrates a flow chart of an example method of managing an input/output interface of a slave device.

Like reference numbers and designations in the various drawings indicate like elements.

### DETAILED DESCRIPTION

In a host-slave system, a slave device can communicate with a host device through an input/output (IO) interface of the slave device coupled to an IO interface of the host device. The IO interfaces may experience a mismatch of voltage configuration between the host device and the slave device, which may lead to compatibility problems or unexpected current leakage. For example, if the IO voltage configuration of the slave device does not match the voltage configuration of the host device, signals may not be effectively transmitted between the host device and the slave device (e.g., due to incorrect determination of voltage levels), devices may malfunction or even be damaged, and/or the static current due to current leakage may increase the power consumption of the host-slave system.

Typically, the host device and the slave device can operate under a communication protocol that specifies the voltage configuration of IO interfaces. By adhering to a communication protocol, the host device and the slave device may effectively communicate with each other. However, compatibility issues may still arise, for example, due to differences between old versions and an updated version of the protocol.

For example, in the field of consumer solid-state drives (cSSDs), different host devices may have different voltage configurations for sideband IO signals and/or system management bus (SMBUS) signals. For instance, some host devices may use 1.8V as the high voltage level when transmitting the sideband IO signals, while some host devices may use 3.3V as the high voltage level when transmitting the sideband IO signals. Further, some manufacturers of the cSSDs may not strictly adhere to the communication protocol when designing the cSSDs.

In some cases, a wide-voltage detection method may be implemented to address the compatibility issue, by allowing IO interfaces to tolerate and operate under a range of voltage levels. However, the wide-voltage detection method may incur the risk of current leakage due to voltage mismatch, which may increase power consumption.

In some cases, an extra signal line can be included in the host-slave system to match the voltage configurations of the host device and the slave device. For example, hardware signals on the extra signal line can be used to identify the voltage configurations of the host device and the slave device, e.g., to identify the voltage level of the sideband IO signals. Further, a communication link can be established to exchange information between the host device and slave device to implement a software-based negotiation process. As an example, an SMBUS link can be established to negotiate the I3C mode of the host-slave system. However, adding the extra signal line may increase the complexity of hardware designs, and the hardware signal may be susceptible to interference. Further, the host device and the slave device may need to strictly adhere to the latest version of the protocol. Otherwise, the host device and the slave device may interpret the hardware signal differently.

The present disclosure provides techniques to manage an IO interface of a slave device. In some implementations, once the slave device is coupled to the host device, the slave device can enter a reset period. During the reset period, the IO interface of the slave device can obtain a voltage level of an input signal received from the host device, and configure a power domain to match the voltage level of the input signal. As such, when the IO interface of the slave device sends an output signal during a communication period that follows the reset period, the output signal can be sent based on the power domain, so that the voltage level of the output signal can be the same as the voltage level of the input signal.

The described techniques can achieve one or more technical effects (e.g., technical advantages and/or benefits). For example, by configuring the power domain to match voltage level of the input signal received from the host device, voltage configurations of the slave device and the host device can be matched, which can mitigate compatibility problems and current leakage problems. For another example, the described techniques can be realized by adding an IO voltage detection circuit, while keeping existing designs of power configuration circuit and power control circuit, which is cost-efficient. In addition, the described techniques do not require adding an extra signal line in hardware designs, and do not require defining negotiation links in software/firmware designs. Further, in some implementations, the IO interface can adjust its voltage configuration on its own, without strictly relying on communication protocols. In some implementations, additional or different technical effects can be achieved.

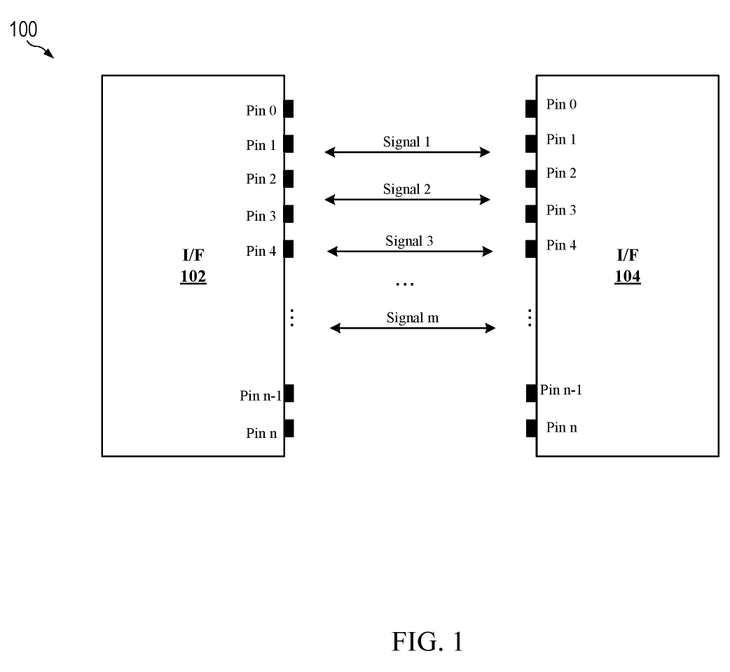

FIG. 1 illustrates an example input/output (IO) interface 102 of a host device and an example input/output interface 104 of a slave device in a host-slave system 100.

A host device, also referred to as a master device, can be coupled to one or more slave devices and configured to initiate and control communication with the slave devices. For example, the host device can manage the timing, data flow, and overall operation of the host-slave system 100. A slave device, also referred to as a peripheral device, can operate under instructions from the host device. For example, the slave device can receive commands and/or requests from the host device, and perform specific tasks accordingly. Examples of a host device include a computer, a smartphone, or a microcontroller unit (MCU) in an embedded system. For instance, a computer acting as a host can communicate with external storage media (e.g., flash memory cards, hard drives), printers, or keyboards, which can function as slave devices.

As shown in FIG. 1, the host device can include an IO interface 102. The IO interface 102 can have a plurality of pins, e.g., Pin 0 and Pin n. The slave device can include an IO interface 104. The IO interface 104 can have a plurality of pins, e.g., Pin 0 and Pin n. The slave device can be connected to the host device by coupling the IO interface 104 to the IO interface 102. For example, each pin of the IO interface 104 can be coupled to a corresponding pin of the IO interface 102, so that input signals (e.g., signals sent from the host device to the slave device) and output signals (e.g., signals sent from the slave device to the host device) can be transmitted between the host device and the slave device. Example signals can include a clock signal, a command signal, and data signals.

In some implementations, a signal can be transmitted through one or more pins of the IO interfaces 102, 104. For example, Signal 1 (e.g., a command signal) can be transmitted through Pin 1 to Pin 4, and Signal 2 (e.g., a clock signal) can be transmitted through Pin 5. A high voltage level at a pin can represent a logical “1”, and a low voltage level at a pin can represent a logical “0”. For instance, when voltage levels of Pin 1 to Pin 4 are set to high, high, low, low, respectively, it may indicate a first command; when voltage levels of Pin 1 to Pin 4 are set to low, high, low, high, respectively, it may indicate a second command. Pins that are used together to transmit one signal can belong to the same power domain group, such that the pins can be powered by the same power domain and operate within the same voltage range, e.g., between the same low voltage level (e.g., 0V or other voltage value) and the same high voltage level (e.g., 1.8V, 3.3V, or other suitable voltage value) during signal transmission. In other words, pins that belong to the same power domain group can have the same voltage when their voltage levels are set high. In some implementations, pins that belong to the same power domain group can be powered using the same voltage regulator.

In some implementations, the IO interface 102 and the IO interface 104 can interact with each other under a communication protocol. A communication protocol can set rules and standards for signal transmission between the host device and the slave device, e.g., which pins are used for transmitting specific signals, timing of signal transitions, how signals are encoded and interpreted, etc. Example communication protocols include Inter-Integrated Circuit (I²C) protocol, Serial Peripheral Interface (SPI) protocol, Peripheral Component Interconnect Express (PCIe) protocol, Serial Advanced Technology Attachment (SATA) protocol, etc. As an example, under PCIe protocol, sideband IO signals can include a reset signal (PERST#), a wake signal (PEWAKE#), and a clock request signal (CLKREQ#); system management bus (SMBUS) signals can include a data signal (SMB_DATA) and a clock signal (SMB_CLK).

In some cases, different communication protocols, or different versions of the same communication protocol may define the high voltage level of a signal differently. For example, different versions of the PCIe protocol may define the high voltage level differently for pins that transmit the sideband IO signals and/or SMBUS signals. To effectively transmit signals (e.g., the sideband IO signals and/or the SMBUS signals), extra steps may be needed to configure the power domain of the IO interface 104. As such, the high voltage level of the pins of the IO interface 104 when sending an output signal can be the same as the high voltage level of the corresponding pins of the IO interface 102 when sending an input signal. For example, the high voltage level of an input signal from the host device may be one of 1.8V or 3.3V. In response to detecting that the high voltage level of the input signal is 1.8V, the IO interface 104 can set the high voltage level of its output signal to be 1.8V, so that signals can be effectively transmitted between the IO interface 102 and the IO interface 104.

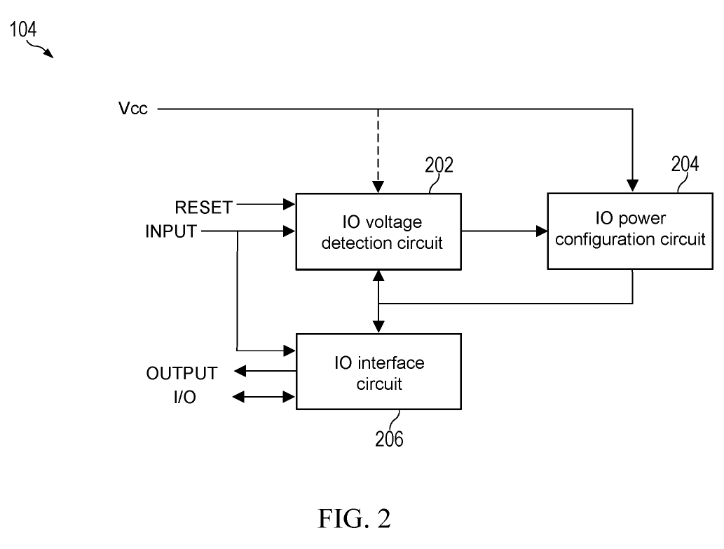

FIG. 2 illustrates a block diagram of example circuits of the IO interface 104 of the slave device. In some implementations, the IO interface can include an IO voltage detection circuit 202 configured to obtain a voltage level of an input signal received from the host device, an IO power configuration circuit 204 configured to determine a power domain of the IO interface 104 based on the voltage level of the input signal, and an IO interface circuit 206 configured to send an output signal to the host device. The power domain can be configured to provide power for pins in the IO interface 104 that are used for transmitting the output signal, so that the voltage level of the output signal can be set based on the power domain.

In some implementations, the IO interface 104 can have more than one power domain. For example, pins that are used to transmit different signals may be powered by different power domains. For instance, a first signal can be transmitted through Pins n-1 and n by the low voltage level being 0V and the high voltage level being 1.8V, and a second signal can be transmitted through Pins 2, 3 and 4 by the low voltage level being 0V and the high voltage level being 3.3V.

In some implementations, the IO voltage detection circuit 202 and the IO power configuration circuit 204 can receive a supply voltage (Vcc). As an example, the supply voltage can be 5V, or other suitable voltage value. The IO voltage detection circuit 202 further receives a reset signal and the input signal from the host device. During a reset period when the IO interface 104 can configure its power domain according to the voltage level of the input signal, the reset signal can be set high. After the power domain is configured, the reset signal can be released, and the IO interface 104 can send signals to the host device during a communication period that follows the rest period.

Further, the IO voltage detection circuit 202 can send a signal to the IO power configuration circuit 204, so that the IO power configuration circuit 204 can configure the power domain of the IO interface 104 and supply power to the IO interface circuit 206. The IO voltage detection circuit 202 can also send the signal to the IO voltage detection circuit 202, e.g., as a feedback signal. The IO interface circuit 206 can communicate with the host device by receiving input signals from the host device and sending output signals to the host device.

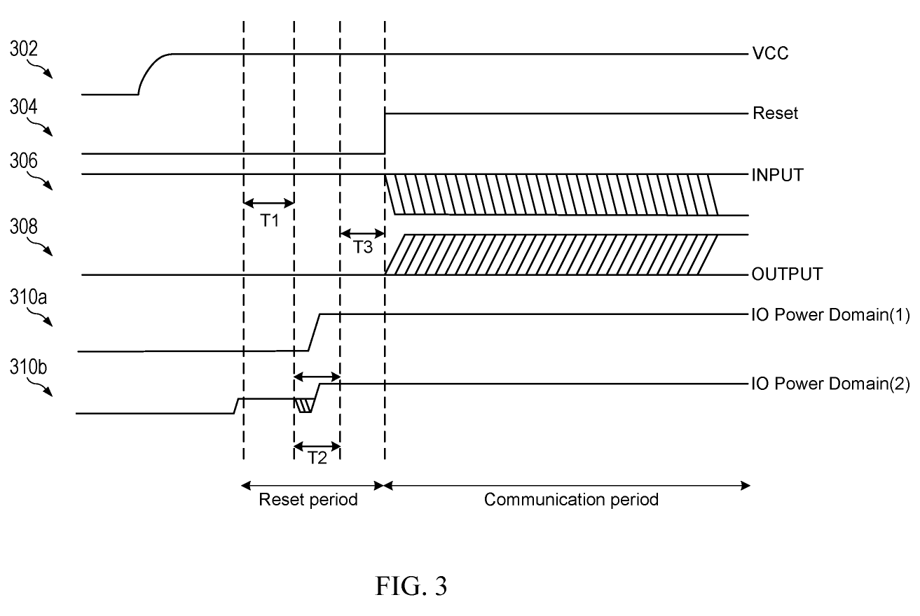

FIG. 3 illustrates a schematic timing diagram of an example signal transmission process. Example voltages during the signal transmission process include a supply voltage (Vcc) 302, a voltage of a reset signal 304, a voltage of an input signal 306 received from the host device, a voltage of an output signal 308 sent to the host device, power domains interfaces 310a, 310b (collectively 310) of the IO interface 104. In some implementations, the supply voltage 302 and the voltage of the reset signal 304 can be applied to the IO interface 104, while the voltage of the input signal 306 and the voltage of the output signal 308 can be applied to specific pins of the IO interface 104 that are used to transmit the corresponding signal. In some implementations, the input signal and the output signal can be sideband IO signals or SMBUS signals.

As shown in FIG. 3, after the slave device is coupled to the host device, the IO interface 104 of the slave device can receive a supply voltage (e.g., 5V, or other suitable voltage value) from the host device. Further, the IO interface 104 can receive the input signal from the host device, e.g., through one or more pins of the IO interface 104. During the reset period when the reset signal is set low, the IO interface can configure its power domain according to the voltage of the input signal 306.

In some implementations, during a first period (T1) of the reset period, the IO interface 104 can obtain a voltage level of the input signal 306. For example, the IO voltage detection circuit 202 can obtain a voltage level of the input signal 306. In some implementations, the input signal 306 can be received through more than one pin of the IO interface 104, and only a portion of the more than one pin are set to the high voltage level when transmitting the input signal. In such case, the IO voltage detection circuit 202 can obtain a voltage level of one of the pins that is set to the high voltage level. As an example, if the input signal is transmitted through Pins 1-4 by setting Pins 1-4 to high, high, low, low, respectively, the IO voltage detection circuit 202 can obtain a voltage level of Pin 1 or Pin 2.

During a second period (T2) of the reset period, the IO interface 104 can configure a power domain 310 based on the voltage level of the input signal. For example, if the voltage level of the input signal is 1.8V, the IO power configuration circuit 204 can configure the power domain 310 to 1.8V, or, if the voltage level of the input signal is 3.3V, the IO power configuration circuit 204 can configure the power domain 310 to 3.3V. The power domain can be configured to supply the high voltage level of the pins that are used to transmit the input signal and output signals corresponding to the input signal. As such, the IO interface 104 can send output signals corresponding to the input signal at the same voltage level as the input signal. In some implementations, as shown in 310a, the voltage of the power domain remains at 0V during T1, and during T2, the IO power configuration circuit 204 can set the voltage of the power domain 310a from 0V to the voltage level of the input signal. In some other implementations, as shown in 310b, the voltage of the power domain is set to a default voltage (e.g., 1.8V) during T1, and during T2, the IO power configuration circuit 204 can adjust the voltage of the power domain 310b from the default voltage to the voltage level of the input signal (e.g., 3.3 V).

After configuring the power domain to match the voltage level of the input signal, during a third period (T3), the reset signal 304 can be released (e.g., set to high), so that the reset period ends, and the communication period starts.

During the communication period, signals can be transmitted between the IO interface 104 of the slave device and the IO interface 102 of the host device. The IO interface 104 can send an output signal to the host device, where the voltage level of the output signal can be set based on the power domain. For example, the input signal 306 and the output signal 308 can be transmitted within the same voltage range, e.g., between the same low voltage level and the same high voltage level.

Similarly, the IO interface 104 can configure more than one power domain by configuring each power domain based on the voltage level of a corresponding input signal. For example, if Pins X1 and X2 are powered by a first power domain and configured to transmit a first signal, the IO interface 104 can configure the first power domain based on the voltage level of the first signal received from the host device during the reset period; if Pins Y1, Y2 and Y3 are powered by a second power domain and configured to transmit a second signal, the IO interface 104 can configure the second power domain based on the voltage level of the second signal received from the host device during the reset period.

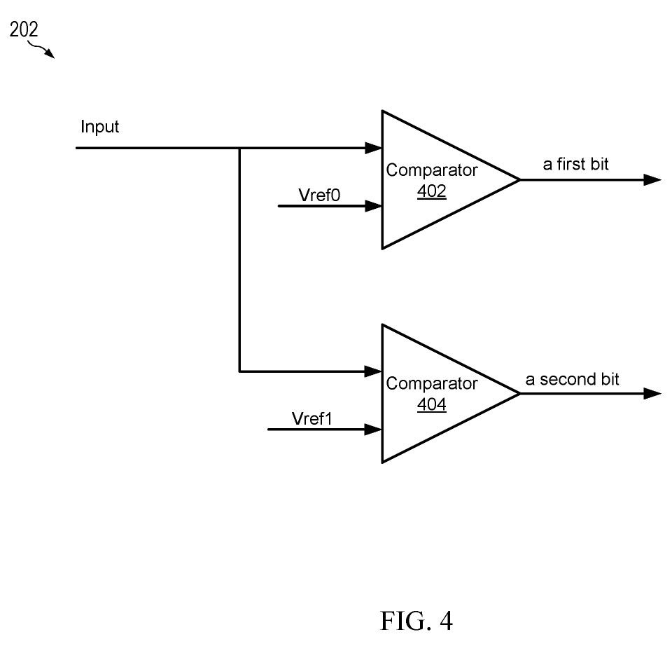

FIG. 4 illustrates a schematic diagram of an example IO voltage detection circuit (e.g., the IO voltage detection circuit 202 of FIG. 2).

In some implementations, the IO voltage detection circuit 202 can include one or more comparators. For example, as shown in FIG. 4, the IO voltage detection circuit 202 can include a first comparator 402 and a second comparator 404. Each comparator may be an operational amplifier having two input terminals and an output terminal.

In some implementations, the first comparator 402 can receive the input signal and a first reference signal (e.g., at 1.5V, or at other suitable voltage level). The first comparator 402 can compare the voltage level of the input signal with the voltage level of the first reference signal, to determine whether the voltage level of the input signal is set high. Further, the first comparator 402 can output a first bit indicating whether the voltage level of the input signal is set high. For example, the first bit being “1” can indicate that the voltage level of the input signal is set high, while the first bit being “0” can indicate that the voltage level of the input signal is set low.

In some implementations, the second comparator 404 can receive the input signal and a second reference signal (e.g., at 3V, or other suitable voltage level). The second comparator 404 can compare the voltage level of the input signal with the voltage level of the second reference signal, to determine whether the input signal corresponds to a first power domain (e.g., 1.8V) or a second power domain (e.g., 3.3V). For example, the second bit being “0” can indicate that the input signal corresponds to the first power domain, while the second bit being “1” can indicate that the input signal corresponds to the second power domain.

It should be noted that the schematic of FIG. 4 is an example only. The IO voltage detection circuit 202 may be designed using different components and/or modules.

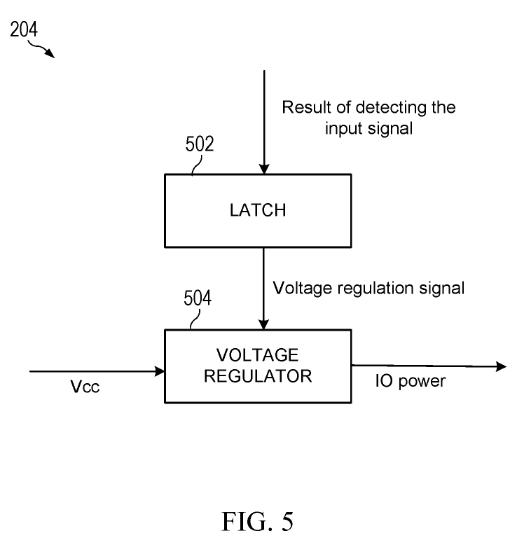

FIG. 5 illustrates a block diagram of an example IO power configuration circuit (e.g., the IO power configuration circuit 204 of FIG. 2).

In some implementations, the IO power configuration circuit 204 can include a latch 502 and a voltage regulator 504. The latch 502 can receive the result of detecting the voltage level of the input signal (e.g., the second bit) from the IO voltage detection circuit 202. The latch 502 can latch the result, e.g., in response to time hysteresis or a trigger signal.

The latch can further send a voltage regulation signal (e.g., an indicator generated based on the second bit) to the voltage regulator 504. The voltage regulation signal can indicate whether to convert the supply voltage (e.g., 5V) to a first output voltage (e.g., 3.3V) or to a second output voltage (e.g., 1.8V). The output voltage of the voltage regulator 504 can be supplied to the IO interface circuit 206.

Examples of the voltage regulator 504 include a low-dropout (LDO) regulator, a buck regulator, or another type of regulator that converts a source of direct current from one voltage level to another. In some implementations, the voltage regulator 504 can be embedded in a power management chip to regulate a voltage for a specific power domain.

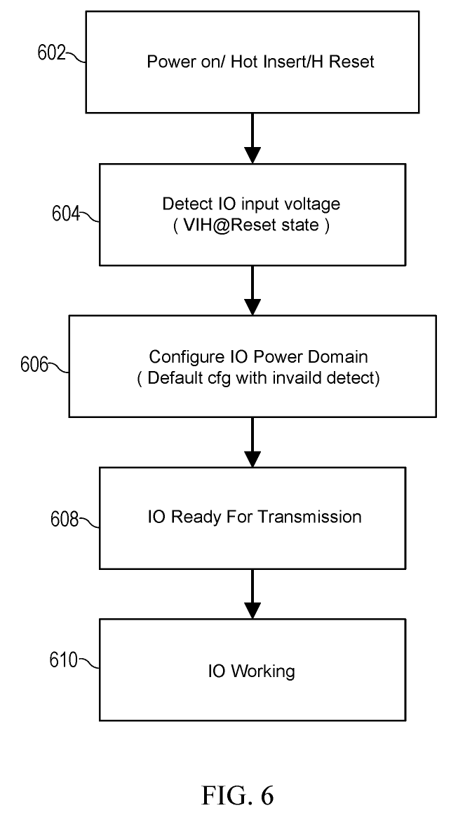

FIG. 6 illustrates an example process 600 of managing an IO interface (e.g., IO interface 104 of FIG. 1) of a slave device.

The operations shown in the process 600 may not be exhaustive and other operations can be performed as well before, after, or in between any of the illustrated operations. Further, some of the operations may be performed simultaneously, or in a different order than shown in FIG. 6. In some implementations, some of the operations may be performed by one or more components of a device or a system, such as a controller of a slave device.

At 602, the slave device is coupled to the host device (e.g., by hot insertion), so that the slave device is powered on. The slave device can enter a reset period, e.g., by setting the voltage of a reset signal to high (H).

At 604, an IO interface of the slave device obtains a voltage level of an input signal received from the host device. For example, the IO interface of the slave device can detect a voltage level of a pin that is set high when transmitting the input signal during the reset period (e.g., by detecting the high voltage level (VIH) of the input signal during the reset period).

At 606, the IO interface of the slave device can configure a power domain to match the voltage level of the input signal, so that when the slave device sends an output signal to the host device, the voltage level of the output signal is the same as the voltage level of the input signal. In some implementations, in case the slave device fails to detect a valid voltage level of the input signal, the power domain can be configured to a default voltage.

At 608, after configuring the power domain to match the voltage level of the input signal, the IO interface of the slave device is ready for signal transmission, and the reset period ends.

At 610, the IO interface of the slave device is working, for example, by communicating with the host device. For example, the IO interface of the slave device receives input signals from the host device, and sends output signals to the host device based on the power domain that is configured to match the voltage level of the input signal detected during the reset period.

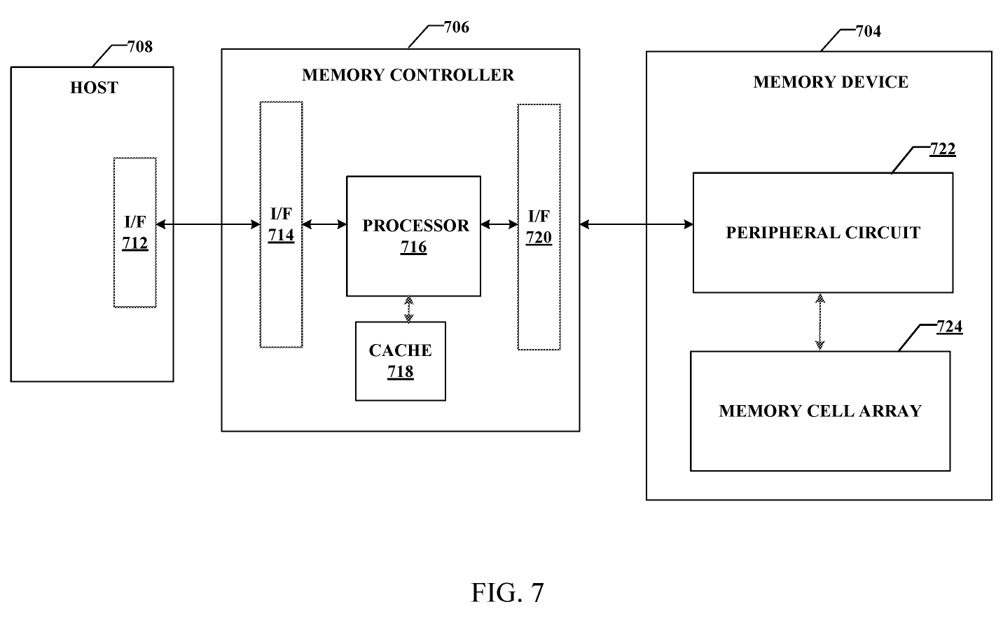

FIG. 7 illustrates a block diagram of an example host-slave system 700 having an example memory system 702. As shown in FIG. 7, the host-slave system 700 can include a host device 708 and a memory system 702 as a slave device. The memory system 702 can have one or more memory devices 704 and a memory controller 706. Examples of the memory devices 704 can include a volatile memory device, such as a dynamic random-access memory (DRAM) and a static random-access memory (SRAM), or a non-volatile memory device, such as a NAND flash memory, a NOR flash memory, an electrically erasable programmable read-only memory (EEPROM), a magnetoresistive RAM (MRAM), and a resistive RAM (ReRAM).

In some implementations, the host device 708 can be a processor of an electronic device, such as a central processing unit (CPU), or a system-on-chip (SoC), such as an application processor (AP). The host device 708 can be configured to send or receive data to or from the memory devices 704. The host device 708 can include an interface 712 configured to communicate with the memory system 702. The IO interface 102 of FIG. 1 can be an example of the interface 712.

The memory controller 706 is coupled to the memory device 704, and the host device 708 and is configured to control the memory device 704. The memory controller 706 can manage the data stored in the memory device 704, and communicate with the host device 708. In some implementations, the memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller 706 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 706 can be configured to control operations of the memory device 704, such as read, erase, and program operations. The memory controller 706 can also be configured to manage various functions with respect to the data stored or to be stored in the memory device 704 including, but not limited to bad-block management, garbage collection, logical-to-physical address conversion, wear leveling, etc. In some implementations, the memory controller 706 is further configured to process error correction codes (ECCs) with respect to the data read from or written to memory device 704. Any other suitable functions may be performed by the memory controller 706 as well, for example, formatting the memory device 704.

In some implementations, the memory system 702 does not include the memory controller 706, and host device 708 is coupled to the memory device 704 directly. For example, the memory controller 706 may be located in the host device 708. Alternatively, the host device 708 may not include the memory controller 706 but may be configured to perform functions similar to what memory controller 706 does as described above.

The memory controller 706 can include one or more processors 716, a host interface 714, a memory interface 720, and a cache 718. The IO interface 104 of FIGS. 1 and 2 can be an example of the host interface 714.

The memory controller 706 can communicate with an external device (e.g., host device 708) according to a particular communication protocol. As shown in FIG. 7, the processor 716 is coupled to the host device 708 through the host interface 714. The host interface 714 allows the memory controller 706 to communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The processor 716 may be coupled to a cache 718. The cache 718 may be configured to store temporary information, e.g., data received from the host device 708 before writing the data to the memory device 704, or data read from the memory device 704 before sending the data to the host device 708.

In some implementations, the memory device 704 can include a memory cell array 724 and peripheral circuits 722 coupled to the memory cell array 724. For example, the memory cell can include memory cells provided in the form of an array of memory strings each extending vertically above a substrate. In some implementations, each memory string includes a plurality of memory cells coupled in series and stacked vertically. Each memory cell can hold a continuous, analog value representing a logic state (i.e., data). The peripheral circuits 722 can include any suitable analog, digital, and mixed-signal circuits for facilitating the operations of the memory cell array. For example, the peripheral circuits 722 can include a page buffer/sense amplifier, a column decoder/bit line driver, a row decoder/word line driver, a voltage generator, control logic, registers, an interface, and a data bus.

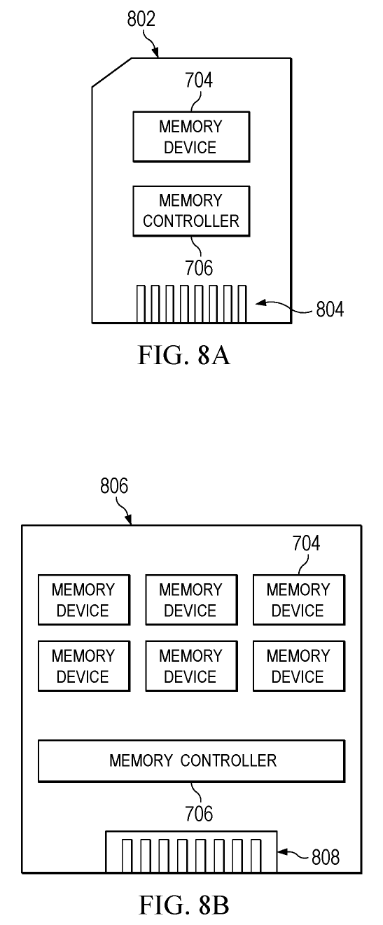

The memory system 702 having the memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 coupling memory card 802 with a host (e.g., host device 708 in FIG. 7). In another example as shown in FIG. 8B, memory controller 706 and multiple memory devices 704 may be integrated into an SSD 806. SSD 806 can further include an SSD connector 808 coupling SSD 806 with a host (e.g., host device 708 in FIG. 7). In some implementations, the storage capacity and/or the operation speed of SSD 806 is greater than those of memory card 802.

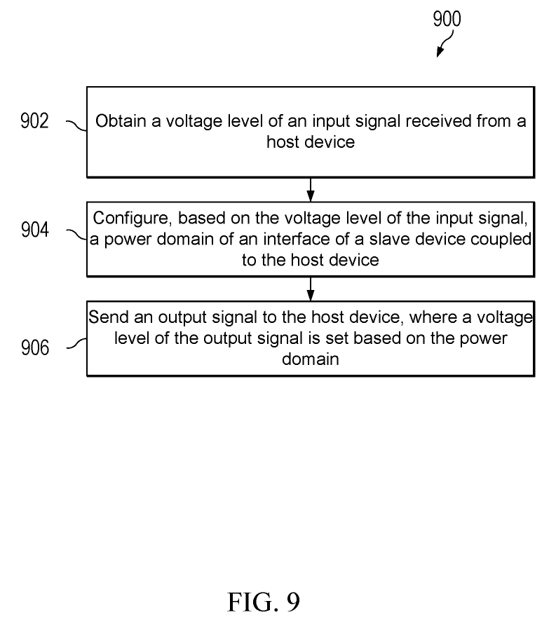

FIG. 9 illustrates a flow chart of an example method 900 of managing an IO interface of a slave device (e.g., the IO interface 104 of FIGS. 1-2). Method 900 can be performed by any suitable device or system as described herein, for example, according to the example techniques described with respect to FIGS. 1-8B. For example, method 900 can be performed by the IO interface of the slave device. The IO interface can include a first circuit (e.g., the IO voltage detection circuit 202 of FIGS. 2 and 4) configured to obtain a voltage level of an input signal received from a host device, a second circuit (e.g., the IO power configuration circuit 204 of FIGS. 2 and 5) configured to determine a power domain of the interface based on the voltage level of the input signal, and a third circuit (e.g., the IO interface circuit 206 of FIG. 2) configured to send an output signal to the host device.

The operations shown in method 900 may not be exhaustive and other operations can be performed as well before, after, or in between any of the illustrated operations. Further, some of the operations may be performed simultaneously, or in a different order than shown in FIG. 9. In some implementations, some of the operations may be performed by one or more components of a device or a system, such as the first circuit, the second circuit, and/or the third circuit of the IO interface.

At 902, the IO interface of the slave device obtains a voltage level of an input signal received from the host device. In some implementations, the input signal can be received through one or more pins of the IO interface. The IO interface can obtain the voltage level of the input signal by detecting a voltage level at a pin among the one or more pins that is set high when receiving the input signal.

At 904, the IO interface of the slave device configures a power domain based on the voltage level of the input signal. In some implementations, the one or more pins that are used to transmit the input signal belong to the same power domain group, and are powered by the same power domain when transmitting an output signal to the host device. The power domain that powers the one or more pins can be configured to match the voltage level of the input signal, for example, during a reset period preceding a communication period when signals are transmitted between the host device and the slave device.

In some implementations, configuring the power domain includes latching, to a latch (e.g., latch 502 of FIG. 5), a first indicator (e.g., the second bit of FIG. 4) indicating the voltage level of the input signal, sending a second indicator from the latch to a voltage regulator (e.g., voltage regulator 504 of FIG. 5), where the second indicator is determined based on the first indicator and indicates the power domain. The power domain can be configured according to the second indicator by configuring an output of the voltage regulator. In some implementations, the voltage regulator is a low drop-out (LDO) regulator or a buck regulator.

In some implementations, a reset signal is released after the power domain is configured to match the voltage level of the input signal, which indicates the reset period transitions into a communication period. The output signal to the host device is sent during a communication period that follows the reset period.

At 906, the IO interface can send an output signal to the host device (e.g., during the communication period), where the voltage level of the output signal is set based on the power domain, so that the voltage level of the output signal can be the same as the voltage level of the input signal.

In some implementations, the input signal and the output signal are sideband input/output signals or system management bus (SMBUS) signals.

While this specification has many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A method, comprising:
obtaining a voltage level of an input signal received from a host device;
configuring, based on the voltage level of the input signal, a power domain of an interface of a slave device coupled to the host device; and
sending an output signal to the host device, wherein a voltage level of the output signal is set based on the power domain.

2. The method of claim 1, wherein the voltage level of the output signal is the same as the voltage level of the input signal.

3. The method of claim 1, wherein the input signal and the output signal are transmitted through one or more pins of the interface, wherein the one or more pins belong to a power domain group and are configured to have the same voltage when voltage levels of the one or more pins are set high.

4. The method of claim 1, comprising:
obtaining a voltage level at a first pin of one or more pins of the interface that belong to a power domain group, wherein the voltage level of the first pin is set high.

5. The method of claim 1, wherein configuring the power domain comprises:
latching, to a latch, a first indicator indicating the voltage level of the input signal;
sending a second indicator from the latch to a voltage regulator, wherein the second indicator is determined based on the first indicator and indicates the power domain; and
configuring the power domain according to the second indicator by configuring an output of the voltage regulator.

6. The method of claim 5, wherein the voltage regulator is a low drop-out (LDO) regulator or a buck regulator.

7. The method of claim 1, further comprising:
releasing a reset signal after the power domain is configured to match the voltage level of the input signal.

8. The method of claim 1, wherein the input signal and the output signal are sideband input/output signals or system management bus (SMBUS) signals.

9. The method of claim 1, wherein the voltage level of the input signal is obtained during a reset period, and wherein the output signal to the host device is sent during a communication period that follows the reset period.

10. The method of claim 1, wherein the slave device is a memory system.

11. A slave device having an interface, wherein the interface comprises:
a first circuit configured to obtain a voltage level of an input signal received from a host device;
a second circuit configured to determine, based on the voltage level of the input signal, a power domain of the interface; and
a third circuit configured to send an output signal to the host device, wherein a voltage level of the output signal is set based on the power domain.

12. The slave device of claim 11, wherein the first circuit comprises:
a first comparator configured to:
receive the input signal and a first reference signal; and
output a first bit indicating whether the voltage level of the input signal is set high; and
a second comparator configured to:
receive the input signal and a second reference signal; and
output a second bit indicating whether the voltage level of the input signal corresponds to a first power domain or a second power domain.

13. The slave device of claim 12, wherein the second circuit comprises:
a latch configured to receive and store the second bit; and
a voltage regulator configured to output, based on the second bit, a voltage corresponding to one of the first power domain or the second power domain.

14. The slave device of claim 11, wherein an output of the second circuit is coupled to the third circuit and provides power for the third circuit.

15. The slave device of claim 11, wherein the first circuit and the second circuit are configured to receive a supply voltage.

16. The slave device of claim 11, wherein the voltage level of the output signal is the same as the voltage level of the input signal.

17. The slave device of claim 11, wherein the interface comprises one or more pins that belong to a power domain group, wherein the one or more pins are configured to transmit the input signal and the output signal, and
wherein the one or more pins are configured to have the same voltage when voltage levels of the one or more pins are set high.

18. A memory system, comprising:
a memory device;
a control circuit; and
an interface configured to:
obtain a voltage level of an input signal received from a host device; determine, based on the voltage level of the input signal, a power domain of the interface; and
send an output signal to the host device, wherein a voltage level of the output signal is set based on the power domain.

19. The memory system of claim 18, wherein the interface comprises:
a first circuit configured to detect the voltage level of the input signal;
a second circuit configured to determine, based on the voltage level of the input signal, the power domain of the interface; and
a third circuit configured to send the output signal to the host device.

20. The memory system of claim 19, wherein the first circuit comprises:
a first comparator configured to receive the input signal and a first reference signal, and output a first bit indicating whether the voltage level of the input signal is set high; and
a second comparator configured to receive the input signal and a second reference signal, and output a second bit indicating whether the voltage level of the input signal corresponds to a first power domain or a second power domain.
